(19) United States
(12) Patent Application Publication
(10) Pub. No.: US 2025/0365888 A1
(43) Pub. Date: Nov. 27, 2025

(54) ELECTRONIC APPARATUS

(71) Applicant: LENOVO (SINGAPORE) PTE. LTD., SINGAPORE (SG)

(72) Inventors: Yudai Tsurumi, YOKOHAMA (JP); Ryota Watanabe, YOKOHAMA (JP); Fusanobu Nakamura, YAMATO (JP); Takanori Hoshino, YOKOHAMA (JP)

(73) Assignee: LENOVO (SINGAPORE) PTE. LTD., SINGAPORE (SG)

(21) Appl. No.: 19/171,703

(22) Filed: Apr. 7, 2025

(30) Foreign Application Priority Data
May 24, 2024 (JP) 2024084847

(51) Int. Cl. H05K 7/20; G06F 1/20

(52) U.S. Cl. CPC H05K 7/20154; G06F 1/203

(57) ABSTRACT

An electronic apparatus includes a storage device that generates heat, a fan having a metal casing, a heat sink provided adjacent to the fan to dissipate heat due to the fact that an airflow by the fan flows toward air vents, a CPU, and a heat pipe for transporting the heat of the CPU to the heat sink. The storage device is thermally connected from a flat surface section of the fan to a flat surface section of the heat sink.

### BACKGROUND OF THE INVENTION

### Field of the Invention

The present invention relates to an electronic apparatus having an electronic component that generates heat.

### Description of the Related Art

An electronic apparatus such as a laptop PC is equipped with a cooling module for cooling a heating element such as a CPU or the like. A cooling module disclosed in Japanese Unexamined Patent Application Publication No. 2024-002802 is configured to include a heat pipe that absorbs and transports heat generated by the CUP or the like, and a heat sink and a fan that dissipate the heat transported by the heat pipe to the outside of a chassis. In Japanese Unexamined Patent Application Publication No. 2023-008497, various heat sinks are exemplified. Further, there is any electronic component other than the CPU such as an SSD that generates heat in the electronic apparatus. In Japanese Unexamined Patent Application Publication No. 2024-046416, a heat dissipating plate is provided on the SSD.

### SUMMARY OF THE INVENTION

In recent electronic apparatuses, since the electronic component such as the SSD has improved performance and has tended to increase the amount of heat generation, there is a concern that the heat dissipating plate alone, as disclosed in Japanese Unexamined Patent Application Publication No. 2024-046416, may not provide sufficient cooling and hence processing capacity may be reduced due to throttling or the like.

The present invention has been made in view of the above problem, and it is an object thereof to provide an electronic apparatus capable of cooling a heat-generating electronic component more efficiently.

In order to solve the problem described above and achieve an object, an electronic apparatus according to one aspect of the present invention includes: a first electronic component which generates heat; a fan equipped with a metal casing; and a heat sink provided adjacent to the fan to dissipate heat due to the fact that an airflow by the fan flows toward air vents, wherein the first electronic component is thermally connected from the metal casing of the fan to the heat sink.

The electronic apparatus according to the present invention can cool the heat-generating electronic component more efficiently.

### BRIEF DESCRIPTION OF THE DRAWINGS

FIG. 1 is a schematic plan view of an electronic apparatus according to one embodiment as viewed from above.

FIG. 2 is a plan view schematically illustrating the internal structure of a chassis.

FIG. 3 is a perspective view of a trailing edge section of the chassis as viewed from the side of a lower surface.

FIG. 4 is a schematic side cross-sectional view of the trailing edge section of the chassis and a surrounding area thereof.

FIG. 5 is a perspective view illustrating a storage device, a heat dissipation structure, and a surrounding area thereof inside the electronic apparatus.

FIG. 6 is an exploded perspective view in which the storage device and a thermal pad in FIG. 5 are removed.

### DETAILED DESCRIPTION OF THE INVENTION

A preferred embodiment of an electronic apparatus according to the present invention will be described in detail below while referring to the accompanying drawings.

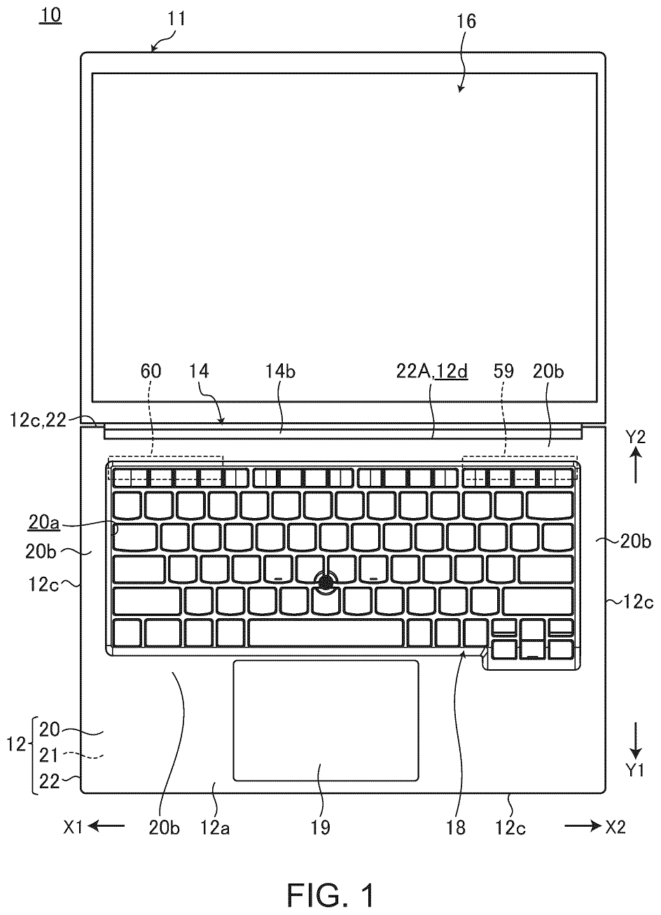

FIG. 1 is a schematic plan view of an electronic apparatus 10 according to one embodiment as viewed from above. As illustrated in FIG. 1, the electronic apparatus 10 of the present embodiment is a clamshell laptop PC. The electronic apparatus 10 is so configured such that a lid body 11 and a chassis 12 are coupled by a hinge 14 to be rotatable relative to each other. In the present embodiment, the electronic apparatus 10 as the laptop PC is exemplified, but the electronic apparatus 10 may also be, for example, a tablet PC, a smartphone, or a handheld game console, other than the laptop PC.

The lid body 11 is a thin, flat box-shaped chassis. The lid body 11 is equipped with a display 16. The display 16 is, for example, an organic EL display or a liquid crystal display.

The chassis 12 is a thin flat box body. A keyboard device 18 and a touch pad 19 are provided on a top surface 12a of the chassis 12. The following description will be made on the chassis 12 and each component equipped therein by referring to the width directions (left and right) of the chassis 12 as X1 and X2 directions, respectively, referring to the depth directions (front and back) of the chassis 12 as Y1 and Y2 directions, respectively, and referring to the thickness directions (up and down) of the chassis 12 as Z1 and Z2 directions, respectively, using the posture of an operator to operate the keyboard device 18 as the basis. Note that the X1 and X2 directions may also be collectively referred to as the X direction, and the Y1 and Y2 directions and the Z1 and Z2 directions may also be referred to as the Y direction and the Z direction in the same way. Each of these directions is defined for convenience of description, and it is, of course, possible to change the direction depending on the usage state, the placement posture, or the like of the electronic apparatus 10.

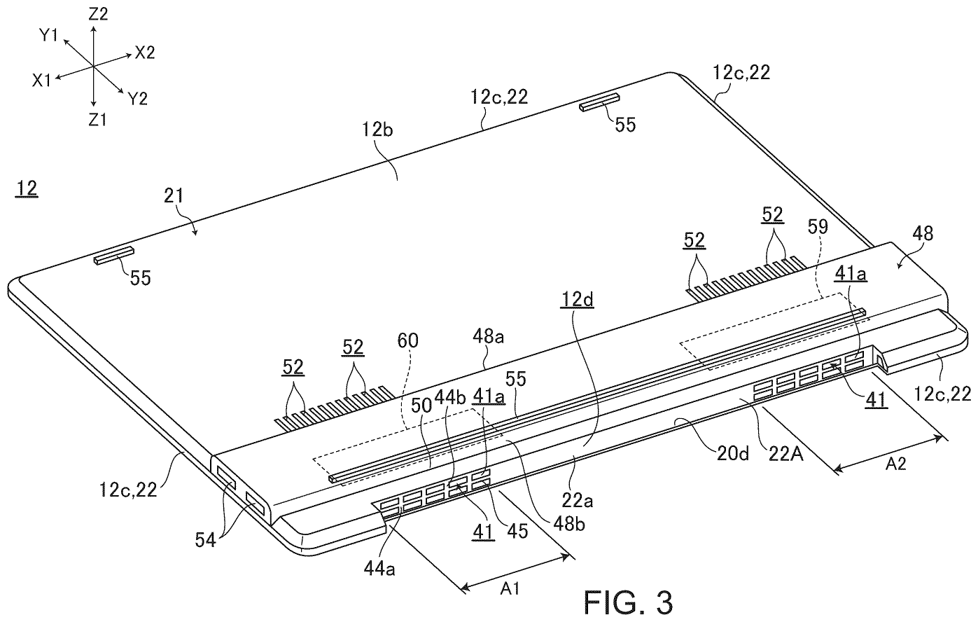

The chassis 12 can be composed of a plate-shaped member 20 that forms the top surface 12a, a cover member 21 that forms a bottom surface 12b, and a standing wall member 22 that forms four side faces 12c. The plate-shaped member 20 has a large rectangular opening 20a in which the keyboard device 18 is placed. A bezel 20b surrounding the keyboard device 18 is formed around the opening 20a. The cover member 21 is formed into a plate shape (see FIG. 3). As will be described later, in the chassis 12 of the present embodiment, a protruding section 48 is provided near the Y2 edge of the cover member 21. The standing wall member 22 is standing between the four side edges of the plate-shaped member 20 and the four side edges of the cover member 21 to form a frame as a whole.

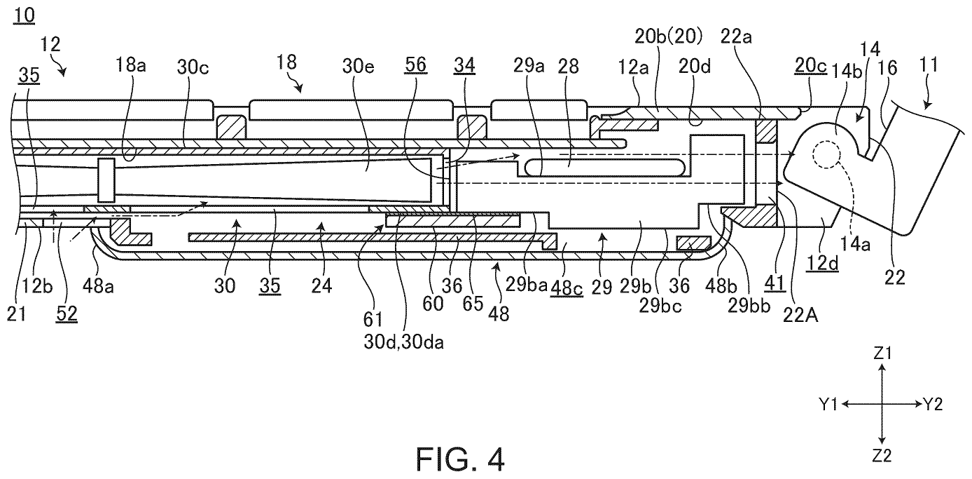

The hinge 14 is placed in a concave hinge placement groove 12d formed on a training edge of the chassis 12 to couple the chassis 12 and the lid body 11. For example, the hinge 14 has a structure in which a hinge shaft 14a as the axis of rotation (see FIG. 4) is supported on both ends of a hinge casing 14b in the longitudinal direction, respectively. The hinge 14 of the present embodiment is formed into a so-called one-bar shape in which the hinge casing 14b is extended along the longitudinal direction of the hinge placement groove 12d. The hinge 14 descends diagonally backward while the hinge casing 14b is rotating together with the lid body 11 (see FIG. 4). The hinge 14 has such a structure as to gain the rotation angle of the lid body 11 in this way, that is, a so-called drop-down structure. Note that the structure of the hinge 14 may also be any structure other than the structure mentioned above.

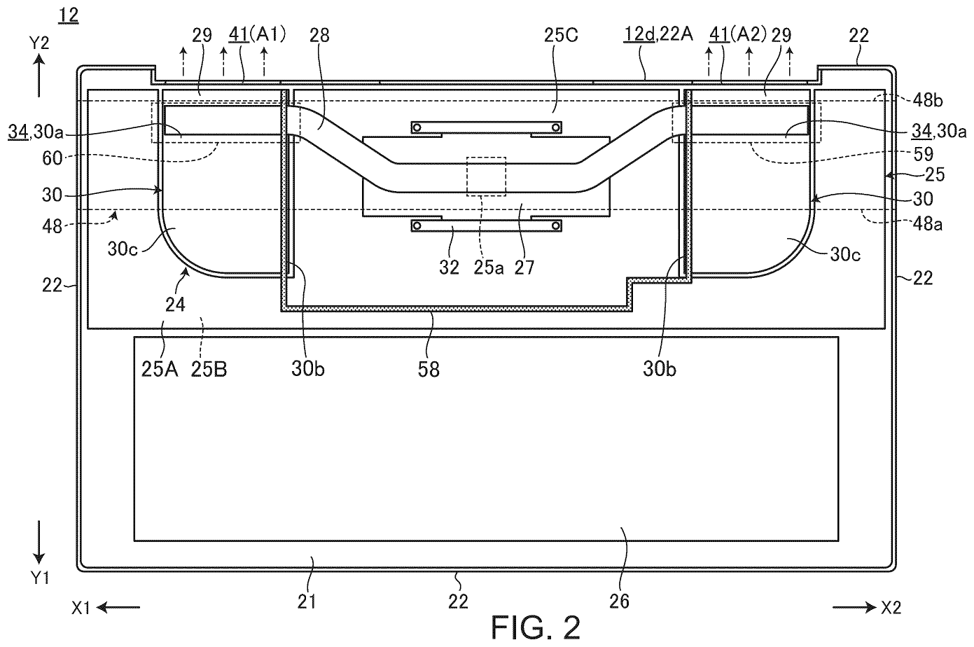

FIG. 2 is a plan view schematically illustrating an internal structure of the chassis 12. FIG. 2 is a view of the internal structure of the chassis 12, in which the plate-shaped member 20 is removed, as viewed from above.

As illustrated in FIG. 2, a cooling module 24, a motherboard 25, and a battery device 26 are housed inside the chassis 12. Inside the chassis 12, electronic components, such as various module cards 59 and a storage device 60 (see FIG. 4), and mechanical components are provided.

The motherboard 25 is a circuit board as a main board of the electronic apparatus 10. The motherboard 25 is placed on the Y2 side of the chassis 12 to extend in the X direction. The battery device 26 is a rechargeable battery that becomes the power supply of the electronic apparatus 10. The battery device 26 is placed on the Y1 side of the chassis 12 to extend in the X direction.

The motherboard 25 of the present embodiment is equipped with a CPU (Central Processing Unit; a second electronic component) 25a. On the motherboard 25, various electronic components other than the CPU 25a, such as a GPU (Graphics Processing Unit), a memory, a communication module, and the like, can be mounted.

For example, the upper surface (first surface 25A) of the motherboard 25 is a mounting surface of the CPU 25a and the like, and the lower surface (second surface 25B) thereof is an attaching surface to the chassis 12.

Next, a configuration example of the cooling module 24 will be described.

The CPU 25a is a heating element largest in amount of heat generation among electronic components equipped inside the chassis 12. The cooling module 24 can absorb and diffuse heat generated by the CPU 25a, and exhaust the heat to the outside of the chassis 12. The cooling module 24 may also be configured to cool any heating element other than the CPU 25a such as the GPU. Further, the storage device 60 (see FIG. 4) also generates a certain amount of heat inside the chassis 12. Especially, with the recent increase in capacity and speed, the storage device 60 tends to increase the amount of heat generation. The storage device 60 and a heat dissipation structure 61 of the storage device 60 will be described later.

As illustrated in FIG. 2, the cooling module 24 of the present embodiment includes a metal plate 27, a heat pipe (heat transport section) 28, a pair of heat sinks 29, 29, and a pair of fans 30, 30.

The metal plate 27 is a thin plate made of a metal having high thermal conductivity such as copper or aluminum. The metal plate 27 of the present embodiment is a copper plate. The metal plate 27 extends in the X direction between the left and right fans 30, 30. Accordingly, the metal plate 27 covers a part (part 25C) of the motherboard 25 arranged between the left and right fans 30, 30, and the CPU 25a mounted in the part 25C from the side of the first surface 25A (from the Z1 side). The metal plate 27 functions as a heat diffusion member to absorb and diffuse the heat of the CPU 25a and the like. The metal plate 27 is connected to the surface of the CPU 25a. Between the metal plate 27 and the CPU 25a, for example, thermally conductive grease and a copper block having approximately the same size as the external shape of the CPU 25a, or the like intervene. Leaf springs 32 are attached to respective edges of the metal plate 27 along the X direction. The leaf springs 32 are parts to force the metal plate 27 onto the CPU 25a.

The heat pipe 28 is a pipe-shaped heat transport device. The heat pipe 28 is constructed by crushing a metal pipe into a thin, flat shape to form the metal pipe into a cross-sectionally elliptical shape, and sealing a working fluid in an inner closed space. As the working fluid, water, an alternative CFC, acetone, butane, or the like can be exemplified. The central part of the heat pipe 28 in the longitudinal direction is fixed to the back sides of the connection surfaces of the metal plates 27 to the CPU 25a. Both ends of the heat pipe 28 are fixed to a surface (upper part 29a) on the Z1 sides of the left and right heat sinks 29, respectively (see FIG. 4). The central part of the heat pipe 28 in the longitudinal direction overlaps with the CPU 25a in the Z direction. Thus, the heat pipe 28 can receive the heat of the CPU 25a transferred to the metal plates 27 efficiently and transport the heat to the heat sinks 29 at both ends thereof with high efficiency.

The heat sink 29 has a structure in which multiple fins formed of thin metal plates are arranged at equal intervals in the X direction. Each fin stands up in the Z direction on a given base plate and extends in the Y direction. A gap through which air delivered from the fan 30 passes is formed between adjacent fins of the heat sink 29. The heat sink 29 is made of a metal having high thermal conductivity such as aluminum or copper. The heat sink 29 is disposed opposite to a side face 30a (exhaust port 34) on the Y2 side of the fan 30.

The pair of fans 30, 30 is placed side by side in the X direction in a way to stride across the part 25C of the motherboard 25 and the metal plates 27 therebetween to face each other. Each fan 30 has the exhaust port 34 on the Y2 side face 30a. The exhaust port 34 is close to and opposite to the heat sink 29 behind it. A gap 56 between the heat sink 29 and the fan 30 is narrowed moderately. The heat sink 29 and the fan 30 may also be in contact with each other. Each fan 30 can have an intake port 35 on the Z2-side lower surface 30d (metal casing) of the upper and lower surfaces 30c and 30d to face the Z direction. The lower surface 30d is a metal material that constitutes part of the chassis of the fan 30. In the case of the present embodiment, the Z1 side upper surface 30c of the fan 30 is in contact with a lower surface 18a of the keyboard device 18 (see FIG. 4).

The fan 30 is a centrifugal fan to rotate, by a motor, an impeller 30e housed in the housing (see FIG. 4). Thus, the fan 30 can discharge, from the exhaust port 34, air inhaled from the intake port 35.

FIG. 3 is a perspective view of a trailing edge section of the chassis 12 as viewed from the side of the lower surface 12b. FIG. 4 is a schematic side-sectional view of the trailing edge section of the chassis 12 and a surrounding area thereof.

As illustrated in FIG. 2 to FIG. 4, the hinge placement groove 12d recessed on the Y1 side is provided on the Y2-side edge of the chassis 12. The hinge placement groove 12d can be composed of a notch portion 20c formed in the plate-shaped member 20 and a back wall 22A formed in part of the Y2-side standing wall member 22.

The notch portion 20c is a recessed portion formed to notch the training edge section of the plate-shaped member 20 on the Y1 side. The notch portion 20c is formed in most of the Y2-side bezel 20b of the keyboard device 18 in the longitudinal direction (X direction).

The back wall 22A is a section in which most of the Y-side standing wall member 22 is recessed toward the Y1 side in the longitudinal direction (X direction). The back wall 22A can be configured as a plate-shaped member standing up along the Z direction. An upper end face 22a of the back wall 22A is provided to come into contact with the lower surface 20d of the plate-shaped member 20. The heat sink 29 is disposed between the back wall 22A and the exhaust port 34 inside the chassis 12. A symbol 36 indicates a frame member.

In the electronic apparatus 10, respective air vents 41 can be divided into an X1-side edge area A1 and an X2-side edge area A2. The air vents 41 exhaust, to the outside of the chassis 12, air ejected from the exhaust ports 34 of the fans 30 and passed through the left and right heat sinks 29.

The air vents 41 penetrate through the back wall 22A in a plate-thickness direction (Y direction). The air vents 41 are partitioned up and down by a horizontal bar-shaped partition wall 45 extending in the X direction.

For example, the air vents 41 are divided into multiple sections 41a in the X direction by multiple pillars 44b lined up along the longitudinal direction (X direction) of the back wall 22A. The pillars 44b are rod bodies extending along the standing direction (Z direction) of the back wall 22A. The air vents 41 are divided into the multiple sections 41a (see FIG. 3). The air vents 41 are placed immediately behind the heat sink 29 to face the heat sink 29.

On the lower surface 12b of the chassis 12, the protruding section 48 protruding downward is formed. The protruding section 48 has a square tube shape long in the X direction and flat in the Z direction. The length of the protruding section 48 in the X direction is over almost the entire width of the chassis 12 in the X direction. The protruding section 48 is provided on the Y2 side of the lower surface 12b in the front-back direction (Y direction). The protruding section 48 has a pair of side walls 48a and 48b extending along the longitudinal direction (X direction). The side wall 48b on the Y2 side is located just before the back wall 22A.

The lower part of the heat sink 29 is composed of a Y1-side flat surface section 29ba, a Y2-side flat surface section 29bb, and a downward protruding section 29bc formed therebetween. An upper part 29a of the heat sink 29, and the lower part 29ba, 29bb, and 29bc thereof are covered with a fin-shaped section in which the upper and lower ends of each fin are bent as in Japanese Unexamined Patent Application Publication No. 2023-008497, or covered with a metal plate provided aside from the fins. The upper and lower parts of the heat sink 29 may not be covered therewith depending on the conditions.

The two flat surface sections 29ba and 29bb are approximately the same height. The Y2-side flat surface section 29bb is relatively small, and hence the downward protruding section 29bc is secured widely. The Y1-side flat surface section 29ba is moderately wide in the Y direction. The downward protruding section 29bc is inserted into an inner space 48c of the protruding section 48 (see FIG. 4), and hence the area of fins is large. The downward protruding section 29bc may be omitted. The back part of the heat sink 29 is facing the air vents 41 penetrating through the inner wall surface of the back wall 22A and the back wall 22A. It is sufficient that the flat surface section 29ba thermally connected to the storage device 60 is formed in the heat sink 29, and the shapes of the other sections are not limited.

As illustrated in FIG. 3 and FIG. 4, bottom air vents 52 to open into the lower surface 12b of the chassis 12 are provided. The bottom air vents 52 are openings for introducing air outside the chassis 12 into the intake port 35 of the fan 30. In the plan view illustrated in FIG. 2, the left and right fans 30 are arranged to straddle the side wall 48a in the Y direction. As illustrated in FIG. 4, the bottom air vents 52 are formed to open into the cover member 21 at a position close to the side wall 48a of the protruding section 48. For example, the bottom air vents 52 can be constructed to extend in the Y direction with multiple slit-shaped openings narrow in the X direction lined up in the X direction. The bottom air vents 52 may also be open from the lower surface 12b of the chassis 12 to the side wall 48a.

The protruding section 48 can be equipped with input/output ports 54 at respective ends (on left and right end faces) thereof in the longitudinal direction. As the input/output ports 54, input/output ports compliant with the HDMI (registered trademark) standard, input/output ports compliant with the USB 3.0 communication standard, or the like can be exemplified. Thus, it is possible for the electronic apparatus 10 to set up the input/output ports 54 that require a certain height while minimizing the thickness of the chassis 12. The protruding section 48 also functions as a rear leg part to lift the rear of the chassis 12 more than the front thereof when the chassis 12 is placed on a placement surface such as a desk surface. Thus, the keyboard device 18 becomes a tilted posture with the front downward when being used, and the operability of the electronic apparatus 10 is improved. A symbol 55 in FIG. 3 indicates rubber legs as leg parts when the electronic apparatus 10 is placed on the placement surface. A rubber leg on the Y2 side is provided on the lower surface of the protruding section 48. In FIG. 4, the illustration of the rubber leg 55 is omitted.

In the electronic apparatus 10, heat generated by the heating elements such as the CPU 25a is transferred to the metal plate 27 and dissipated, and transported efficiently to the left and right heat sinks 29 through the heat pipe 28. The left and right fans 30 inhale outside air (cold air) from the bottom air vents 52 into the intake port 35 and discharge the inhaled air from the exhaust ports 34.

The air discharged from the exhaust ports 34 of the left and right fans 30 passes through the heat sinks 29 to cool the heat sinks. The air (warm air) after cooling the heat sinks is discharged to the outside of the chassis 12 through the respective air vents 41 belong to the areas A1 and A2. In other words, the heat sinks 29 are provided adjacent to the fans 30 to dissipate heat due to the fact that an airflow by the fans 30 flows toward the air vents 41. A symbol 58 in FIG. 2 indicates an airtight wall made of a sponge or rubber to control the airflow by the fans 30 to be directed to the heat sinks 29 and the air vents 41.

In the inner space 48c of the protruding section 48, the module cards 59 are provided at a position close to the X2 side and corresponding to the area A2. For example, each of the module cards 59 is a WWAN (Wireless Wide Area Network) card or an AI (Artificial Intelligence) accelerator. The storage device (first electronic component) 60 is provided at a position close to the X1 side and corresponding to the area A1 in the inner space 48c of the protruding section 48. Each of the module cards 59 and the storage device 60 has a thin, approximately rectangular plate shape long in the X direction. Since the module cards 59 and the storage device 60 are provided in the inner space 48c, the space efficiency is high. The module cards 59 and the storage device 60 are provided at approximately symmetrical positions.

Next, the storage device 60 and the heat dissipation structure 61 that dissipates heat from the storage device 60 will be described.

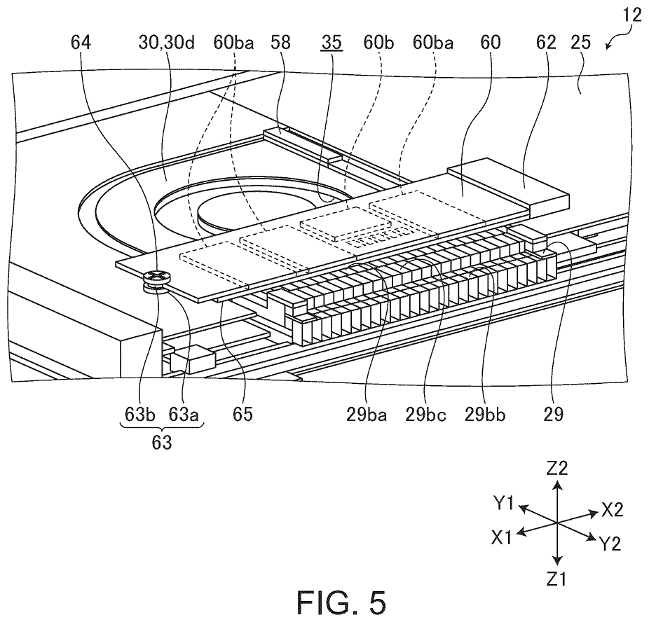

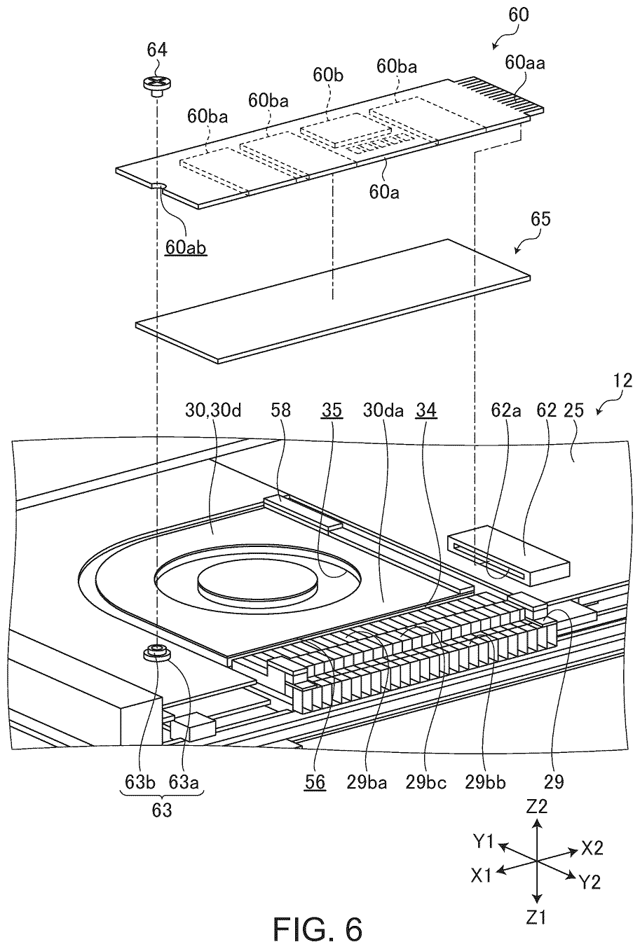

FIG. 5 is a perspective view illustrating the storage device 60, the heat dissipation structure 61, and a surrounding area thereof provided inside the electronic apparatus 10. FIG. 6 is an exploded perspective view in which the storage device 60 and a thermal pad 65 in FIG. 5 are removed. The heat dissipation structure 61 includes the heat sink 29, the fan 30, and the storage device 60.

The storage device 60 is a card-type electronic module having an approximately rectangular substrate 60a slightly long in the left-and-right direction. A connection terminal 60aa is provided at one end of the substrate 60a (on the X2 side in this case), and a semicircular notch 60ab is formed at the other end (on the X1 side in this case). A chip 60b including plural storage elements 60ba is mounted on the substrate 60a. The chip 60b is surface-mounted on an upper surface 60d basically on the Z1 side. The storage elements 60ba have flat shapes, and the Z1 side thereof lie in the same plane. The storage elements 60ba are relatively large in area and generate large amounts of heat. The storage device 60 may also have a thermally conductive cover in contact with the storage elements 60ba to cover almost the entire surface on the Z1 side. In this example, the length of the storage device 60 in the X direction is slightly longer than the fan 30 and the heat sink 29. The storage device 60 is, for example, an SSD (Solid State Drive).

A connector 62 is provided near the right edge of the motherboard 25. The connection terminal 60aa is inserted into and connected to a slot 62a of the connector 62. The connector 62 is one type of card edge type socket compliant, for example, with the M. 2 (M dot two) standard. A boss 63 is provided near the right edge of the chassis 12. The boss 63 is suitable for fixing the storage device 60 the dimensions of which are standardized, which has a stepped, cylindrical shape composed of a base 63a and a protruding section 63b. A female screw is formed in a hollow part of the protruding section 63b. The protruding section 63b of the boss 63 is constructed to fit into the notch 60ab.

Thus, the connector 62 into which the connection terminal 60aa is fit is provided on the X2 side as one side across the fan 30 and the heat sink 29 along the X direction perpendicular to the Y direction in which the fan 30 and the heat sink 29 are lined up, and the boss 63 into which the notch 60ab is fit is provided on the X1 side as the other side. The connector 62 and the boss 63 act as fixing means of the storage device 60, which are located on the extension of the gap 56.

As illustrated in FIG. 6, the intake port 35 of the fan 30 has a circular shape. The fan 30 has an arc shape in a 90-degree range on the X1 side and the Y1 side, but has a straight line shape on the Y2 side and the X2 side. Therefore, in a part on the Y2 side of the intake port 35 on the lower surface 30d, a flat surface section 30da having a moderate area continuous in the X direction along the gap 56 is secured. The flat surface section 29ba of the heat sink 29 and the flat surface section 30da of the fan 30 are almost the same length in the X direction, lined up across the gap 56, and equal to each other in height.

The connection terminal 60aa is inserted into the slot 62a while holding the storage device 60 slightly diagonally, and the storage device 60 is then made flat and fixed by placing the periphery of the notch 60ab on the base 63a of the boss 63 and tightening the screw 64 into the protruding section 63b. The storage device 60 can be removed and replaced.

The thermal pad 65 is pasted on the upper side of the storage device 60. The thermal pad 65 is one type of TIM (Thermal Interface Material), which can transfer heat of the chip 60b to an object efficiently. The thermal pad 65 is made of a silicon material and has elasticity. The thermal pad 65 comes into contact with the chip 60b and is moderately compressed. The thermal pad 65 has an area enough to be able to come into contact with one or more storage elements 60ba that generate large amounts of heat among the storage elements of the chip 60b, and covers almost the entire upper side of the storage device 60 in this example. The thermal pad 65 may be omitted depending on the conditions.

By the way, since the connector 62 and the boss 63 serving as a standard for fixing the storage device 60 are located across the gap 56 on the extension of the gap 56, the chip 60b of the storage device 60 is in contact with and thermally connected to the flat surface section 30da of the fan 30 and the flat surface section 29ba of the heat sink 29 through the thermal pad 65.

According to such a configuration, the storage device 60 can use not only the heat sink 29 but also the flat surface section 30da of the fan 30 as heat dissipation means, and hence the storage device 60 can be cooled more efficiently. Since the heat sink 29 can be used as heat dissipation means shared between the CPU 25a and the storage device 60, it is efficient. Although the fan 30 blows air to the heat sink 29, since the flat surface section 30da as a metal casing is also cooled along with the blowing of air, the storage device 60 can be cooled. Further, the amount of heat generation of the CPU 25a may become large depending on the processing load and hence the temperature of the heat sink 29 may increase, but the flat surface section 30da of the fan 30 is unaffected by the heat of the CPU 25a so that heat can be dissipated appropriately from the storage device 60.

While the heat pipe 28 is thermally connected to the Z1 side of the heat sink 29, the storage device 60 is thermally connected to the Z2 side. In other words, since the heat pipe 28 and the storage device 60 are thermally connected to the opposite sides of the heat sink 29, mutual thermal influence can be reduced. Since there is no dedicated heat dissipation means for the storage device 60, the number of parts can be reduced.

The flat surface section 29ba and the flat surface section 30da are good balance because the contact areas with the storage device 60 through the thermal pad 65 are about the same, but the contact areas may differ to some extent depending on the heat conditions and the like.

The flat surface sections 29ba and 30da are moderately wide in the Y direction and hence the storage device 60 can be placed. The area of the intake port 35 has some leeway so that there will be no problem even if the area is somewhat covered with the storage device 60. Since the lengths of the flat surface sections 29ba and 30da in the X direction are slightly shorter than the storage device 60, the storage device 60 can be placed astride the flat surface sections 29ba and 30da in the X direction. Since the lengths of the flat surface sections 29ba and 30da in the X direction are moderately long and the gap 56 is moderately narrow, the contact area through the thermal pad 65 is wide. The plural storage elements 60ba that generate large amounts of heat in the storage device 60 overlap with the flat surface sections 29ba and 30da in the X direction and the Y direction except the intake port 35 and the gap 56, the heat is transferred appropriately.

A user of the electronic apparatus 10 often puts his or her hands in spaces on both the left and right sides of the touch pad 19 as palm rests on the plate-shaped member 20 as the upper surface of the chassis 12 (see FIG. 1). These portions are on the Y1 side and the Z1 side of the chassis 12. The storage device 60 is provided in the inner space 48c of the protruding section 48 corresponding to the Y2 side and the Z2 side of the chassis 12, and besides, the fans 30, the airtight wall 58, and the battery device 26 act as partitions between the storage device 60 and the surrounding of the touch pad 19. Therefore, the storage device 60 has almost no thermal effect on the palm rest portions, and hence the user does not feel any discomfort.

The heat dissipation structure 61 mentioned above dissipates heat from the storage device 60, but a similar structure may also be applied to any other electronic components generating heat such as the module cards 59.

The respective fans 30 can also have exhaust ports on side faces 30b (see FIG. 2) facing each other in opposite directions in addition to the exhaust ports 34 mentioned above, and can further have any air vents in the rear center of the chassis other than the air vents 41 in the left and right areas A1 and A2. The exhaust ports of the side faces 30b of the left and right fans 30 may face each other across the part 25C to blow air to both the upper and lower surfaces of the motherboard 25 and exhaust the air from the air vents in the rear center.

The present invention is not limited to the aforementioned embodiment, and changes can be, of course, made freely without departing from the scope of the present invention.

1. An electronic apparatus comprising:
a first electronic component which generates heat;
a first fan equipped with a metal casing; and
a first heat sink adjacent to the fan to dissipate heat by an airflow from the fan that flows towards air vents,
wherein the first electronic component is thermally connected between the metal casing of the fan and the heat sink.

2. The electronic apparatus according to claim 1 further comprising:
a second fan;
a second heat sink;
a second electronic component which generates heat; and
a cooling module including a heat transport section which transports heat of the second electronic component between the second fan and the second heat sink.

3. The electronic apparatus according to claim 2, wherein the heat transport section and the first electronic component are thermally connected to opposite sides of the first and second heat sinks.

4. The electronic apparatus according to claim 1, wherein
the first electronic component, the first fan, and the first heat sink are housed inside a flat-shaped chassis, and the chassis has:
a protruding section that protrudes from a lower surface of the chassis and extends along a width direction, and
input/output ports on end sides of the protruding section, and
the first electronic component is in the protruding section.

5. The electronic apparatus according to claim 1, wherein
the first electronic component has a substrate equipped with a connection terminal on one end and a notch on another other end, and
a connector, into which the connection terminal is configured to fit, is on one side of the first electronic component and a boss, into which the notch is configured to fit, is on another side across the first fan and the first heat sink along a direction orthogonal to a direction in which the first fan and the first heat sink are lined up.
